(19) United States
(12) Patent Application Publication
(10) Pub. No.: US 2026/0165083 A1
(43) Pub. Date: Jun. 11, 2026

(54) System and Method for Precisely Controlling Zonal Temperatures of Electrostatic Chucks

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/972,861

(22) Filed: Dec. 7, 2024

(51) Int. Cl. H01L 21/683; H01L 21/67

(52) U.S. Cl. CPC H10P 72/722; H10P 72/0602

(57) ABSTRACT

The present invention provides a system and method for precise temperature control of electrostatic chucks (ESCs) in semiconductor manufacturing. The system features a control circuit with a thermal feedback loop and pulse-width modulation (PWM) for dynamic power adjustment, ensuring rapid response and resistance to noise. The ESC is divided into multiple zones, each equipped with a heating unit and temperature sensor, with calibration procedures generating reference voltages for accurate zonal temperature management under varying cold plate temperatures.

### FIELD

The present invention relates to temperature control systems for electrostatic chucks (ESCs) used in semiconductor manufacturing processes. Specifically, it addresses a novel method and system for precise temperature control of ESCs using a novel control circuit and calibration procedure that ensures fast response times, high accuracy, and immunity to noise and external interference.

### BACKGROUND

ESCs are critical components in semiconductor manufacturing, particularly in plasma-based processes such as etching and deposition. These processes demand precise and consistent temperature control across the ESC surface to maintain uniformity in substrate processing. However, achieving this level of precision is challenging due to interferences from plasma and electromagnetic fields from RF power generators.

Conventional methods for ESC temperature control often rely on simple feedback loops or basic calibration techniques that may not respond effectively to changes in operating conditions. These systems are also prone to disturbances from noise, such as variations in RF-generated electromagnetic fields, which can cause fluctuations in temperature and degrade process uniformity. Additionally, achieving the necessary speed and precision for temperature adjustments during an etching or other advanced semiconductor process remains a significant limitation.

The present invention introduces a novel system and method for ESC temperature control that overcomes these challenges. By employing an innovative control circuit featuring thermal feedback loops and robust calibration procedures, the system provides precise, real-time temperature adjustments with immunity to various interferences. The calibration procedure enables dynamic adaptation to changing process conditions, enhancing temperature stability and reliability. This robust and efficient approach ensures consistent substrate processing, even in environments with significant electromagnetic interference or rapid plasma-induced thermal fluctuations.

### SUMMARY

The present invention provides a novel system and method for precise temperature control of ESCs in semiconductor manufacturing processes. The system introduces a control circuit and calibration procedure that ensure accurate and stable temperature regulation under varying process conditions. The invention addresses challenges such as temperature calibration under varied process conditions and noise from electromagnetic interference, enabling robust and reliable ESC performance.

In some embodiments, the control circuit includes a thermal feedback loop with a pulse-width modulation (PWM) power delivery mechanism. Temperature sensors embedded in the top dielectric layer of the ESC provide real-time temperature data, which is used to dynamically adjust the PWM duty cycles to maintain precise temperature control. The control system is designed to provide fast response times and resistance to noise, including disturbances caused by RF power generators.

In some implementations, the calibration procedure includes generating reference voltages for the control circuits of the heating units by testing under various temperatures for the cold plate and zones on ESC surface. Before initiating the calibration procedure by a system controller, an ESC surface temperature measurement mechanism needs to be placed.

In one embodiment, a lookup table is created that correlates required ESC surface temperatures at different zones to cold plate temperatures and the respective reference voltages for each control circuit.

This lookup table allows the system to infer optimal reference voltages for different operating conditions. In other implementations, a neural network is trained using calibration data to infer the reference voltages dynamically during operation. The neural network provides greater flexibility and adaptability for handling complex thermal interactions and process variability.

In some embodiments, the calibration procedure is performed prior to processing, where the system operates in a calibration mode under the control of the system controller. The system tests each heating unit under selected cold plate temperatures and records the reference voltages.

The generated data is stored in a storage unit of the system controller, which can use either the lookup table or neural network during process execution to maintain zonal temperatures accurately.

This invention provides a robust and efficient solution for ESC temperature management, offering enhanced precision, fast response, and resistance to noise. The system is applicable to single-zone and multi-zone ESC configurations, ensuring consistent substrate processing across a variety of semiconductor manufacturing processes, including etching.

### BRIEF DESCRIPTIONS OF THE DRAWINGS

The clarity of the embodiments is enhanced by referring to the following description in conjunction with the accompanying drawings:

FIG. 1A: Illustrates an exemplary process system, including a temperature control system integrated with an electrostatic chuck (ESC).

FIG. 1B: Provides a schematic functional block diagram of a heater unit designed to regulate the temperature of a specific zone on the ESC.

FIG. 2A: Demonstrates a first implementation of an ESC, showing the ESC divided into three concentric zones, each independently controlled for distinct temperature regulation.

FIG. 2B: Showcases a second implementation of an ESC, where the ESC is configured with a grid of independently controlled zones to achieve precise temperature control across the surface.

FIG. 3: Highlights a schematic diagram of the control circuits for the ESC temperature control system, incorporating a thermal feedback loop to dynamically adjust zonal temperatures.

FIG. 4A: Presents a flowchart detailing the process for calibrating the ESC and determining reference voltages for the control circuits under varying conditions.

FIG. 4B: Showcases a flowchart of the method for temperature control across the zonal ESC, illustrating the use of calibration data to maintain precise temperatures during operation.

### DETAILED DESCRIPTIONS

To foster a comprehensive understanding, this description elaborates on specific implementations of the current invention. While specific details are provided for elucidation, adjustments and variations that align with the following claims are deemed acceptable. Some established procedures and components are selectively detailed to underscore the unique facets of the invention.

### DEFINITION

Electrostatic Chuck (ESC): A device used in semiconductor manufacturing to securely hold a substrate, such as a semiconductor wafer, during processing by using electrostatic forces.
Process Chamber: A vacuum chamber where plasma-based semiconductor processes, such as etching or deposition, are performed.
Zonal Temperature Control: A method of independently controlling the temperature of different regions (zones) on the surface of the ESC to ensure uniform or customized thermal conditions across the substrate.
Thermal Feedback Loop: A control mechanism that adjusts heating power in real-time based on temperature sensor data and a predetermined reference voltage for a control circuit to maintain a target temperature within a specified range.
Pulse-Width Modulation (PWM): A technique used in the control circuit to regulate power delivery to a heater by modulating the duty cycle of electrical pulses.
Calibration Procedure: A pre-processing step where the system determines reference voltages for precise temperature control, often involving testing with an ESC surface temperature calibration.
Lookup Table: A data structure generated during calibration that correlates target ESC temperatures to cold plate temperatures and reference voltages of the control circuits.
Neural Network: A machine learning model trained using calibration data to infer reference voltages.
Cold Plate: A cooling mechanism integrated with the ESC, used to regulate its base temperature by circulating coolant through internal channels in a metal plate.
Heating Unit: A component embedded within the ESC, typically including a heater, a temperature sensor, and a control circuit, responsible for localized temperature control in a specific zone of the ESC.
Temperature Sensor: A device, such as a diode, transistor, or resistor, embedded within the ESC or cold plate to measure temperature.
Control Circuit: An electronic system that processes temperature data and adjusts power delivery to the heater, ensuring precise and stable temperature control.
Reference Voltage: A predefined voltage value used as a target in the control circuit's feedback loop to regulate the ESC's temperature.
Plasma Ion Flux: The flow of ions generated in the plasma process chamber, which can affect the ESC surface temperature due to ion bombardment.

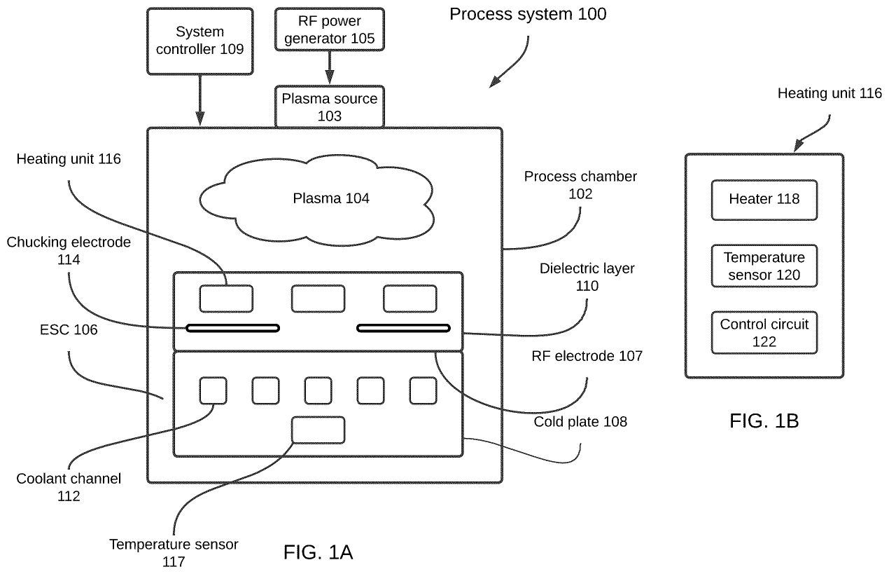

FIG. 1 depicts a schematic diagram of a semiconductor manufacturing process system, denoted as 100. The process system 100 includes a process chamber 102 configured to create a vacuum environment for processing. The process system 100 further comprises a plasma source 103, powered by an RF power generator 105, for generating plasma 104 within the process chamber 102. An electrostatic chuck (ESC) 106 is utilized to hold a substrate, such as a semiconductor wafer, during processing.

Precise control of the substrate's temperature during processing is critically important for many processes. The temperature is controlled by balancing the heating and cooling of the ESC 106. A cold plate 108 provides a cooling mechanism by circulating coolant through one or more coolant channels 112. The cold plate 108 is typically made from a piece of metal like aluminum. The cold plate 108 further comprises a temperature sensor 117 for measuring the temperature near the coolant channel 112. The temperature sensor 117 needs to be carefully placed to avoid interference from the coolant flow while ensuring accurate measurements. Multiple sensors may be utilized to measure the temperature distribution in the cold plate 108.

Atop the cold plate 108 is a dielectric layer 110, typically constructed from a material like aluminum nitride. Chuck electrodes 114 are embedded within the dielectric layer 110 to provide electrostatic chucking force to hold the substrate. On the surface of the ESC 106, grooves (not shown in FIG. 1) are utilized to supply high-pressure inert gas flow. Helium is typically used for this function. Stability for the substrate is achieved through a balance between the electrostatic force and the pressure difference between the inert gas layer and the vacuum within the process chamber 102.

In some implementations, the ESC 106 receives RF power from another RF power generator (not shown in FIG. 1) via an RF electrode 107, generating a bias voltage for the substrate. The bias voltage is utilized to accelerate ions in the plasma 104, which are essential for high aspect ratio (HAR) etching.

The dielectric layer 110 further includes one or more heating units 116 to heat the surface of the ESC 106. A schematic diagram of the heating unit 116 is shown in FIG. 1B. The heating unit 116 includes a heater 118. The heater 118 may be a resistor or an active device, such as a MOSFET or a bipolar transistor. The heating unit 116 also includes a temperature sensor 120 embedded within the dielectric layer 110 for measuring the temperature of the surface of the ESC 106. Depending on the implementation, the temperature sensor 120 may include diodes, transistors, or resistors. The heating unit 116 further comprises a control circuit 122 for controlling temperature of a defined surface area or a zone of the ESC 106.

The process system operates under the supervision of a system controller 109.

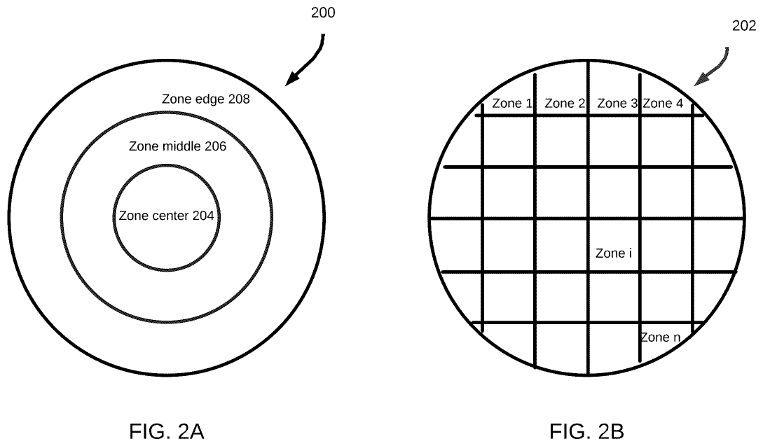

The ESC 106 may include multiple zones for providing distinct temperatures. Referring to FIG. 2A, a to view of one embodiment, denoted as 200, illustrates three zones of the chuck: zone center 204, zone middle 206, and zone edge 208. Each zone is designed to provide an independently controlled temperature. Each zone includes an independent heating unit 116. Each zone may also include one or more temperature sensors 120.

When multiple zones are used, one or more temperature sensors 117 may also be included for the cold plate 108.

FIG. 2B depicts another embodiment, denoted as 202, where the ESC 106 is divided into zones represented by a grid. The zones are labeled as zone 1, zone 2, zone 3, zone 4, . . . , zone i, . . . , and zone n. Each zone provides an independently controlled temperature via an independent heating unit 116. Similarly, additional sensors 117 may be placed within the cold plate 108.

In one implementation, the zones may be thermally isolated. In another implementation, the zones may not be thermally isolated.

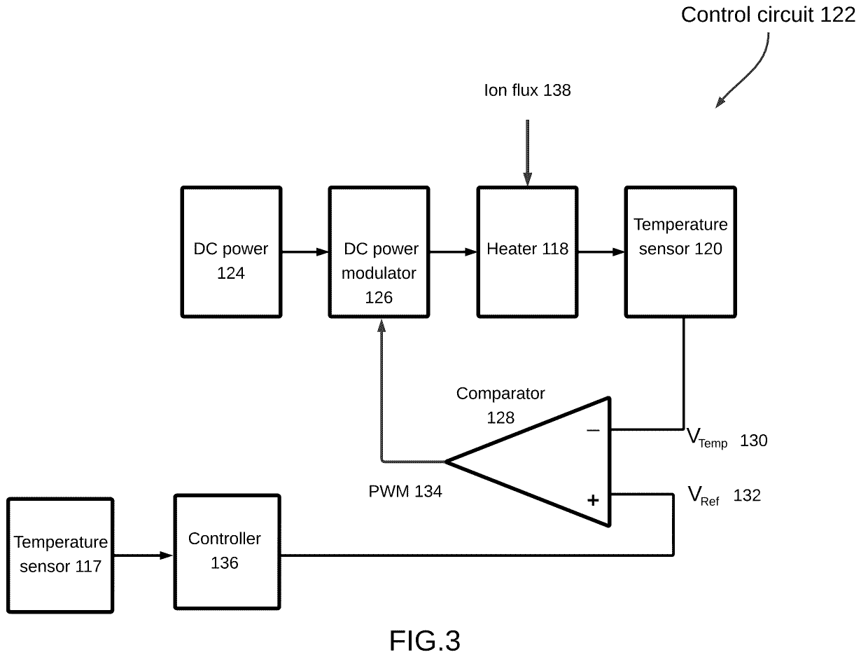

FIG. 3 illustrates an exemplary control circuit 122 based on a thermal feedback loop for controlling surface temperature of the ESC 106. In the embodiment shown in FIG. 3, the control circuit 122 comprises a DC power 124 drawn from a conventional power supply, which may be an AC power source. An AC/DC converter is required to convert the power from AC to DC if the power is derived from the AC power source.

In one aspect of the embodiment, block 126 modulates DC power 124 using a PWM signal 134. In one implementation, the PWM signal includes a squared waveform. The ratio of the on-time to the period of the signal is defined as the duty cycle. The output power of block 126, in PWM form, is utilized by the heater 118. The power received by the heater 118 is a function of the amplitude and duty cycle of the PWM signals. In one implementation, the modulated DC power may also be converted to back to the DC power before it is delivered to the heater 118.

It should be noted that in the process chamber 102 with plasma 104, the surface of the ESC 106 can also be affected by ion flux 138, particularly if a high bias voltage is applied to the substrate for accelerating the ions.

The temperature sensor 120 measures the temperature of the dielectric layer 110 near its surface. The temperature sensor 120 outputs a voltage signal. Comparator 128 takes one input from the output of temperature sensor 120, denoted as V_{Temp} 130, and another input from a reference generated by controller 136, denoted as V_{Ref} 132. The output of comparator 128, in PWM form, is coupled to an input of DC power modulator 126 to modulate the DC power 124, completing the thermal feedback loop. The temperature will oscillate around a small value set by the reference voltage. The reference voltage V_{Ref} is determined by the controller 136 or the system controller 109, which may utilize a lookup table or a neural network to infer the reference voltage. The lookup table and the neural network are created during a calibration phase to be described.

It should be noted that the power required to sustain the temperature level around which oscillates also depends on other factors, such as the temperature of the cold plate 108. Therefore, the controller 136 or the system controller 109 must generate V_{Ref} by accounting for these factors to control the temperature precisely through a calibration procedure.

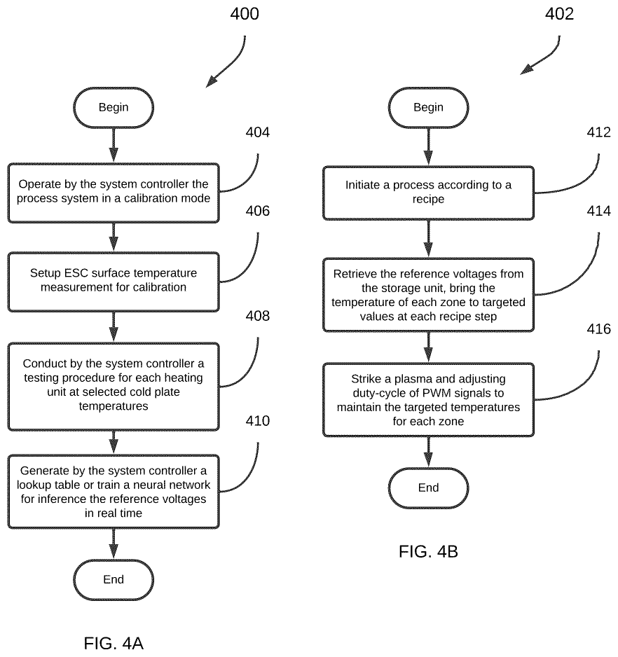

FIG. 4A shows a flowchart for a calibration process to determine reference voltages for the control circuit 122. Process 400 begins with step 404, where the process system operates in calibration mode under the system controller 109. In step 406, a mechanism for measuring ESC surface temperature is set up. In one case, a specially designed apparatus with a shape similar to a wafer is placed on the top of the ESC. The apparatus includes an array of high precision temperature sensors for measuring the surface temperatures across the ESC surface. In step 408,

the system controller 109 runs a testing procedure for each heating unit 116 at selected cold plate temperatures. After completing the test procedure, reference voltages for each heating units for different cold plate temperatures at each zone are determined. In step 410, the generated data is stored in the storage unit of the system controller 109. In one implementation, a lookup table is created for deriving the voltage reference in real time based on a recipe. In another implementation, a neural network is trained based on the data. The reference voltages can be determined in real time by operating the neural network in inference mode.

FIG. 4B illustrates a flowchart for controlling the temperature of the zonal ESC. Process 402 begins with step 412, where a process is initiated according to a specified recipe. In step 414, calibration data stored in the system controller 109 is retrieved. The system controller 109 then generates reference voltages for each heating unit 116 at each recipe step for each ESC zone. Either a lookup table or a neural network is used to infer the appropriate reference voltages based on the cold plate temperatures.

In step 416, plasma 104 is generated, and the PWM signals are dynamically adjusted by the control circuits to achieve the required zonal temperatures.

This invention provides an effective solution for controlling ESC temperatures. The system and method maintain desired temperatures robustly by dynamically adjusting the PWM signal's duty cycle to mitigate noise or interference. For example, if PWM signals are altered due to electromagnetic fields from RF power generators, the duty cycle is rapidly adjusted to maintain the required temperature.

Additionally, in scenarios where ion flux acts as an additional heating source, the control circuit automatically reduces the power required to maintain the targeted temperature. This adaptive capability ensures precise and efficient temperature regulation across the ESC zones under varying process conditions.

1. An electrostatic chuck (ESC) of a process system, comprising:
a plurality of zones, each zone including:
a heating unit configured to adjust the temperature of the zone;
a temperature sensor configured to measure the temperature of the zone; and
a cold plate including one or more temperature sensors and coolant channels;
a control circuit of the heating unit, including:
a thermal feedback loop configured to dynamically adjust the power delivered to a heater of the heating unit based on the measured temperature of the zone; and
a pulse-width modulation (PWM) mechanism configured to regulate the power delivered to the heating unit for achieving a targeted temperature for the zone as stipulated in a recipe;
a controller configured to generate a reference voltage for a comparator, wherein the reference voltage is derived from a lookup table or a neural network stored in a storage unit of the controller; and
wherein the lookup table or the neural network is generated based on data obtained from a calibration procedure.

2. The system of claim 1, wherein the controller is a controller for the ESC and/or a system controller for the process system.

3. The system of claim 1, wherein the lookup table includes the reference voltages that correlate to cold plate temperatures and zonal temperatures for each zone.

4. The system of claim 1, wherein the neural network is trained using data generated from the calibration procedure, and the neural network dynamically infers reference voltages for precise temperature control during processing.

5. The system of claim 1, wherein the control circuit includes a PWM generator configured to adjust the duty cycle of the power delivered to each heating unit based on a feedback signal from the temperature sensor.

6. The system of claim 1, wherein the control circuit further includes a comparator that compares a reference voltage with the measured temperature signal to generate the feedback signal for controlling the power delivered to the heater.

7. The system of claim 1, wherein the control circuit compensates for process noise and external electromagnetic interference by dynamically adjusting the duty cycle of the PWM signal.

8. The system of claim 1, wherein the control circuit operates in a thermal feedback loop that continuously adjusts the heating power to minimize deviations from the target temperature in each zone.

9. A control circuit for temperature regulation in an ESC system, comprising:
a plurality of zones, each configured to independently adjust temperature;
a thermal feedback loop for each zone, configured to dynamically adjust the power delivered to a heating unit of the zone based on the measured temperature of the zone;
a PWM used to regulate the power delivered to each heating unit by adjusting the duty cycle of the electrical signals;
a comparator configured to compare a measured temperature signal from the temperature sensor with a reference voltage to generate a feedback signal, wherein the reference voltage is determined based on a lookup table or a neural network; and
a calibration procedure configured to generate data used to create the lookup table or to train the neural network.

10. The control circuit of claim 9, wherein the calibration procedure involves placing a surface temperature measurement apparatus on the surface of the ESC.

11. The control circuit of claim 10, wherein the calibration procedure is configured to calibrate the surface temperatures using the surface temperature measurement apparatus at different temperatures of a cold plate of the ESC.

12. The control circuit of claim 9, wherein the ESC includes a plurality of zones arranged in a grid format.

13. The control circuit of claim 9, wherein the ESC includes a plurality of concentric zones.

14. The control circuit of claim 9, wherein the ESC further comprises a controller configured to operate the calibration procedure.

15. The control circuit of claim 9, wherein the control circuit is controlled directly by a system controller of a process system hosting the ESC system.

16. A method for regulating the temperature of an ESC in a semiconductor processing system, comprising:
providing an ESC with a plurality of zones, each zone configured with a heating unit and a temperature sensor;
determining reference voltages for the heating units under varying conditions through a calibration procedure, wherein the varying conditions including zonal temperatures and cold plate temperatures;
measuring the temperature of each zone using the corresponding temperature sensor;
dynamically adjusting power delivered to each heating unit based on the measured temperature of the corresponding zone using a thermal feedback loop including a comparator which takes a reference voltage as an input, wherein the reference voltage is derived from the determined reference voltages; and
regulating the power delivered to the heating units by using a PWM signal.

17. The method of claim 16, further comprising generating a lookup table during the calibration procedure, the lookup table correlating reference voltages with zonal temperatures and cold plate temperatures.

18. The method of claim 16, wherein the calibration procedure includes training a neural network using calibration data to dynamically infer reference voltages for temperature control during processing.

19. The method of claim 16, wherein dynamically adjusting power includes compensating for noise and electromagnetic interference by modifying the duty cycle of the PWM signals.

20. The method of claim 16, further comprising using the thermal feedback loop to continuously adjust heating power in real time to minimize deviations from the target temperatures for each zone.
